(19) United States
(12) Patent Application Publication
(10) Pub. No.: US 2023/0172039 A1
(43) Pub. Date: Jun. 1, 2023

(54) MASK FRAME ASSEMBLY AND METHOD OF MANUFACTURING DISPLAY APPARATUS BY USING THE SAME

(71) Applicant: Samsung Display Co., Ltd., Yongin-si (KR)

(72) Inventors: Mina Woo, Yongin-si (KR); Sujung Kang, Yongin-si (KR); Sanghoon Kim, Yongin-si (KR); Seoyeon Kim, Yongin-si (KR); Jongsung Park, Yongin-si (KR); Hongkyun Ahn, Yongin-si (KR); Jiyun Chun, Yongin-si (KR); Sangwoo Jo, Yongin-si (KR)

(21) Appl. No.: 17/987,640

(22) Filed: Nov. 15, 2022

(30) Foreign Application Priority Data
Nov. 29, 2021 (KR) 10-2021-0167725

(51) Int. Cl. H01L 51/00; H01L 51/56; C23C 14/04; C23C 14/24

(52) U.S. Cl. CPC H01L 51/0011; H01L 51/001; H01L 51/56; C23C 14/042; C23C 14/24

(57) ABSTRACT

A mask frame assembly includes: a mask including a plurality of opening portions; and a frame coupled to an edge of the mask, wherein the mask includes: first shielding portions extending in a first direction and parallel to each other; second shielding portions parallel to each other and extending in a second direction crossing the first direction, such that the plurality of opening portions are defined together with the first shielding portions; and a first protrusion on the first shielding portion, wherein, in the second direction, a distance from an opening portion on one side of the first shielding portion is different from a distance from an opening portion on another side of the first shielding portion.

### CROSS-REFERENCE TO RELATED APPLICATION

The present application claims priority to and the benefit of Korean Patent Application No. 10-2021-0167725, filed on Nov. 29, 2021, in the Korean Intellectual Property Office, the entire disclosure of which is incorporated herein by reference.

### BACKGROUND

### 1. Field

Aspects of one or more embodiments relate to a mask frame assembly and a method of manufacturing a display apparatus by using the same.

### 2. Description of the Related Art

In general, when a display apparatus including an organic light-emitting display apparatus or the like is manufactured, various layers are formed by deposition or the like. For example, in the case of an organic light-emitting display apparatus, a hole injection layer, a hole transport layer, an electron transport layer, or an electron injection layer may be formed on a substrate by using a deposition apparatus during a manufacturing process. During this process, a material may be deposited at a preset region on the substrate by using a mask.

The above information disclosed in this Background section is only for enhancement of understanding of the background and therefore the information discussed in this Background section does not necessarily constitute prior art.

### SUMMARY

Aspects of one or more embodiments relate to a mask frame assembly and a method of manufacturing a display apparatus by using the same, and for example, to a mask frame assembly with a reduced probability of defects in a manufacturing process and a method of manufacturing a display apparatus by using the mask frame assembly.

However, in the case of a mask frame assembly used during some deposition processes, a portion of a mask may be in contact with a substrate when the mask frame assembly is used, and accordingly, the instances of defects in the display device during the manufacturing process may be relatively high.

Aspects of one or more embodiments include a mask frame assembly with a relatively reduced probability of defects in a manufacturing process and a method of manufacturing a display apparatus by using the mask frame assembly. However, the embodiments are merely examples, and do not limit the scope of the disclosure.

Additional aspects will be set forth in part in the description which follows and, in part, will be apparent from the description, or may be learned by practice of the presented embodiments of the disclosure.

According to some embodiments, a mask frame assembly includes a mask including a plurality of opening portions, and a frame coupled to an edge of the mask, wherein the mask includes first shielding portions extending in a first direction and parallel to each other, second shielding portions parallel to each other and extending in a second direction crossing the first direction, so that the plurality of opening portions are defined together with the first shielding portions, and a first protrusion on the first shielding portion, wherein, in the second direction, a distance from an opening portion on one side of the first shielding portion is different from a distance from an opening portion on another side of the first shielding portion.

According to some embodiments, the first protrusion may extend in the first direction.

According to some embodiments, the plurality of opening portions may include a first opening portion and a second opening portion, the second opening portion being spaced apart from the first opening portion in the second direction, and the mask frame assembly may further include a third protrusion contacting the first opening portion and circumferentially surrounding the first opening portion, wherein a portion of the third protrusion is on the first shielding portion.

According to some embodiments, the mask frame assembly may further include a fourth protrusion contacting the second opening portion and circumferentially surrounding the second opening portion, wherein a portion of the fourth protrusion is on the first shielding portion.

According to some embodiments, a height of the first protrusion, a height of the third protrusion, and a height of the fourth protrusion may be equal.

According to some embodiments, the mask may further include a second protrusion on the second shielding portion, wherein, in the first direction, a distance from an opening portion on one side of the second shielding portion is equal to a distance from an opening portion on another side of the second shielding portion.

According to some embodiments, the second protrusion may extend in the second direction.

According to some embodiments, the plurality of opening portions may include a first opening portion and a third opening portion, the third opening portion being spaced apart from the first opening portion in the first direction, and the mask frame assembly may further include a third protrusion contacting the first opening portion and circumferentially surrounding the first opening portion, wherein a portion of the third protrusion is on the second shielding portion.

According to some embodiments, the mask frame assembly may further include a fifth protrusion contacting the third opening portion and circumferentially surrounding the third opening portion, wherein the fifth protrusion is on the second shielding portion.

According to some embodiments, a height of the first protrusion, a height of the third protrusion, and a height of the fifth protrusion may be equal.

According to some embodiments, the first protrusion and the second protrusion may be provided as one body.

According to some embodiments, a method of manufacturing a display apparatus includes forming a first spacer to be positioned in a first peripheral area between a first display area and a second display area so that a distance from the first spacer to the first display area is different from a distance from the first spacer to the second display area, the first display area and the second display area of a mother glass being positioned to adjacent to each other in a first direction, arranging a first opening portion and a second opening portion of a mask to respectively correspond to the first display area and the second display area of the mother glass, wherein the mask is arranged so that a first protrusion on a first shielding portion of the mask overlaps the first spacer, and depositing a deposition material on the mother glass through the first opening portion and the second opening portion of the mask.

According to some embodiments, the forming of the first spacer may include forming a first dam portion circumferentially surrounding the first display area, wherein a portion of the first dam portion passes through the first peripheral area, forming a second dam portion circumferentially surrounding the second display area, wherein a portion of the second dam portion passes through the first peripheral area, and forming the first spacer to be between the first dam portion and the second display area so that a distance of the first spacer from the first dam portion is different from a distance of the first spacer from the second dam portion.

According to some embodiments, the forming of the first spacer may include simultaneously forming the first dam portion, the second dam portion, and the first spacer by using a same material.

According to some embodiments, the arranging of the mask may include arranging a third protrusion to overlap the first dam portion, the third protrusion contacting the first opening portion and circumferentially surrounding the first opening portion, wherein a portion of the third protrusion is on the first shielding portion, and arranging a fourth protrusion to overlap the second dam portion, the fourth protrusion contacting the second opening portion and circumferentially surrounding the second opening portion, wherein a portion of the fourth protrusion is on the first shielding portion.

According to some embodiments, the method may further include forming a second spacer to be positioned in a second peripheral area between a third display area and the first display area of the mother glass so that a distance from the second spacer to the first display area is equal to a distance from the second spacer to the third display area, the third display area being spaced apart from the first display area in a second direction crossing the first direction.

According to some embodiments, the forming of the second spacer may include forming a third dam portion circumferentially surrounding the third display area, wherein a portion of the third dam portion passes through the second peripheral area, and forming the second spacer to be positioned between the first dam portion and the third dam portion so that a distance of the second spacer from the first dam portion is equal to a distance of the second spacer from the third dam portion.

According to some embodiments, the forming of the first spacer and the forming of the second spacer may be performed simultaneously.

According to some embodiments, the forming of the first spacer and the forming of the second spacer may include simultaneously forming the first dam portion, the second dam portion, the third dam portion, the first spacer, and the second spacer by using a same material.

According to some embodiments, the arranging of the mask may include arranging a second protrusion to overlap the second spacer, the second protrusion being on a second shielding portion of the mask, arranging a third protrusion to overlap the first dam portion, the third protrusion contacting the first opening portion, circumferentially surrounding the first opening portion, and being on the second shielding portion, and arranging a fifth protrusion to overlap the third dam portion, the fifth protrusion contacting a third opening portion of the mask corresponding to the third display area of the mother glass, circumferentially surrounding the third opening portion, and being on the second shielding portion.

Other aspects, features, and characteristics of embodiments according to the present disclosure will become more apparent from the detailed description, the claims, and the drawings.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a schematic plan view of a display apparatus being manufactured by a method of manufacturing a display apparatus, according to some embodiments;

FIG. 2 is a cross-sectional view of a manufacturing apparatus for a manufacturing method, according to some embodiments;

FIG. 3 is a schematic exploded perspective view of a mask frame assembly, according to some embodiments;

FIG. 4 is a plan view of a mask of a mask frame assembly, according to some embodiments;

FIG. 5 is a schematic cross-sectional view of the mask, taken along a line II-II′ of FIG. 4;

FIG. 6 illustrates a simulation result indicating a degree of bending of a first shielding portion of a mask frame assembly, according to some embodiments;

FIG. 7 is a schematic cross-sectional view of the mask, taken along a line III-III′ of FIG. 4;

FIG. 8 is a schematic cross-sectional view of the display apparatus, taken along a line I-I′ of FIG. 1;

FIG. 9 is a schematic cross-sectional view of the display apparatus, taken along a line IV-IV′ of FIG. 1;

FIG. 10 is a diagram for describing a position of a mask of a mask frame assembly, according to some embodiments;

FIG. 11 is a schematic cross-sectional view of the display apparatus, taken along a line V-V′ of FIG. 1;

FIG. 12 is a diagram for describing a position of a mask of a mask frame assembly, according to some embodiments; and

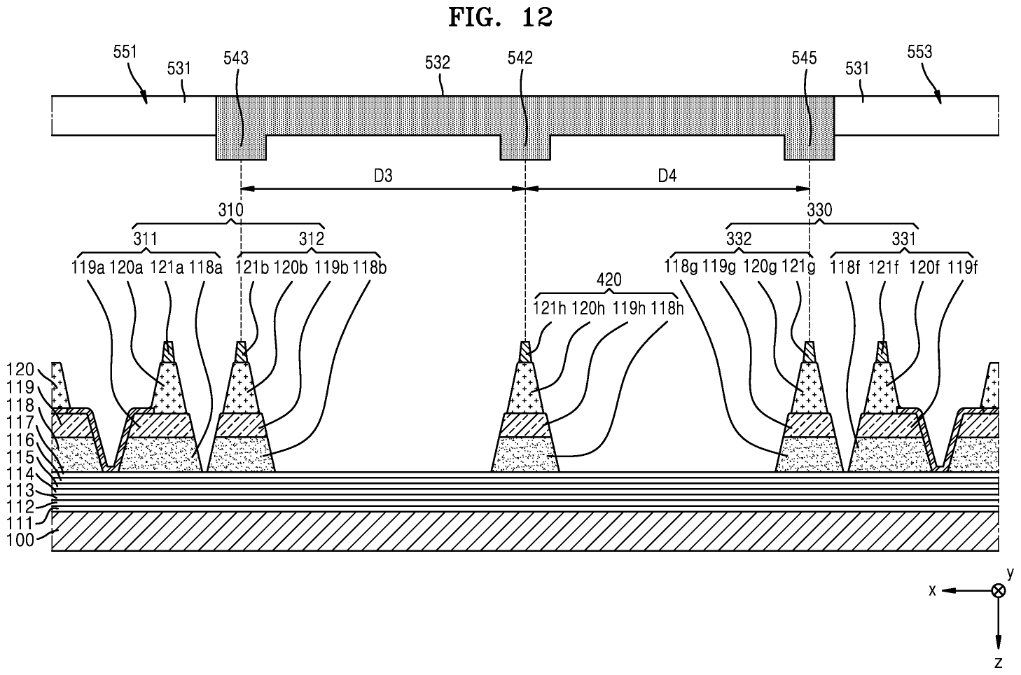

FIG. 13 is a schematic cross-sectional view of a portion of a display apparatus manufactured by a manufacturing method, according to some embodiments.

### DETAILED DESCRIPTION

Reference will now be made in more detail to aspects of some embodiments, which are illustrated in the accompanying drawings, wherein like reference numerals refer to like elements throughout. In this regard, the present embodiments may have different forms and should not be construed as being limited to the descriptions set forth herein. Accordingly, aspects of some embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Characteristics and features of some embodiments of the present disclosure, and implementation methods thereof will be clarified through following embodiments described with reference to the accompanying drawings. The disclosure may, however, be embodied in many different forms and should not be construed as limited to the embodiments set forth herein.

Hereinafter, aspects of some embodiments will be described in more detail with reference to the accompanying drawings, wherein the same or corresponding elements are denoted by the same reference numerals throughout and some repeated description thereof may be omitted.

It will be understood that when an element, such as a layer, a film, an area, or a plate, is referred to as being “on” another element, the element may be directly on the other element or intervening elements may be present therebetween. Sizes of elements in the drawings may be exaggerated or contracted for convenience of description. In other words, because sizes and thicknesses of elements in the drawings are arbitrarily illustrated for convenience of description, the following embodiments are not limited thereto.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another or may represent different directions that are not perpendicular to one another.

It will be understood that although the terms “first,” “second,” etc. may be used herein to describe various elements, these elements should not be limited by these terms. These elements are only used to distinguish one element from another.

In the following embodiments, the singular forms include the plural forms unless the context clearly indicates otherwise.

It will be further understood that the terms “comprises” or “comprising” used herein specify the presence of stated features or elements, but do not preclude the presence or addition of one or more other features or elements.

As used herein, “A and/or B” is used herein to select only A, select only B, or select both A and B. In addition, “at least one of A and B” is used to select only A, select only B, or select both A and B.

In the case where a certain embodiment may be implemented differently, a specific process order may be performed in the order different from the described order. As an example, two processes that are successively described may be performed substantially simultaneously (or concurrently) or performed in the order opposite to the order described.

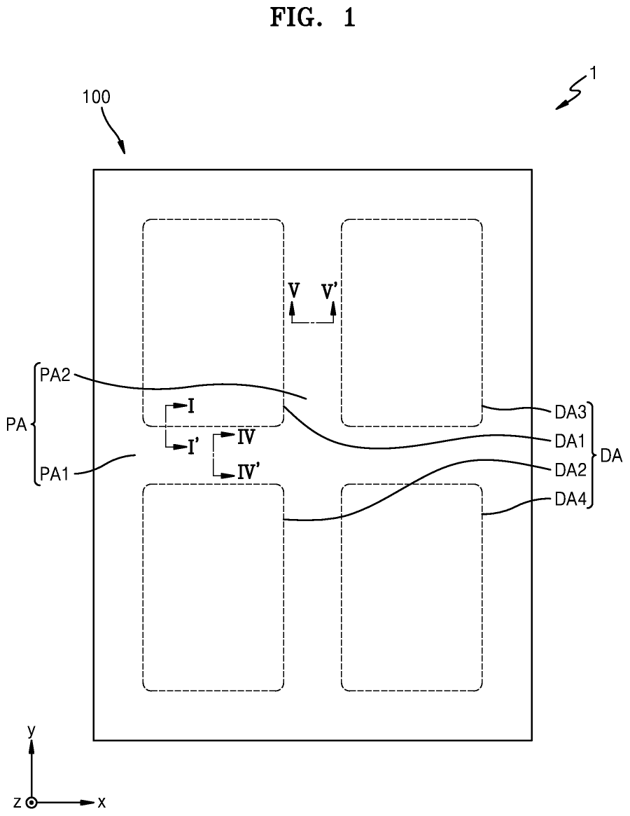

FIG. 1 is a schematic plan view of a display apparatus 1 being manufactured by a method of manufacturing a display apparatus, according to some embodiments. As illustrated in FIG. 1, a plurality of display apparatuses are manufactured simultaneously (or concurrently) by simultaneously (or concurrently) forming a plurality of display portions on one mother glass 100 and then cutting the mother glass 100 along a periphery of each of the plurality of displays.

The mother glass 100 may include glass, a metal, or a polymer resin. The mother glass 100 needs to be flexible or bendable. In this case, the mother glass 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. Various modifications may be made to the mother glass 100. For example, the mother glass 100 may have a multi-layered structure including two layers each including the aforementioned polymer resin, and a barrier layer between the two layers, the barrier layer including an inorganic material (e.g., silicon oxide, silicon nitride, or silicon oxynitride).

As illustrated in FIG. 1, the mother glass 100 may include a plurality of display areas DA (e.g., DA1 through DA4, although embodiments according to the present disclosure are not necessarily limited to four display areas, and some embodiments may include additional display areas or fewer display areas) and a peripheral area PA outside the display areas DA, and the mother glass 100 may have an upper surface (in a +z direction) and a lower surface (in a −z direction).

The display areas DA may be areas where images are displayed, and a plurality of pixels may be arranged in the display areas DA. When viewed in a direction substantially perpendicular to the mother glass 100 (e.g., when viewed in a plan view or a direction that is perpendicular or normal with respect to a plane parallel to the mother glass), each of the display areas DA may have various shapes such as a circle, an oval, a polygon, or a certain-shaped figure. FIG. 1 illustrates that each of the display areas DA has a shape that is substantially a rectangle with round edges, although embodiments are not limited thereto.

The mother glass 100 may include a plurality of display areas DA. For example, a first display area DA1 may be positioned at an upper left side of the mother glass 100, and a third display area DA3 may be positioned at an upper right side of the mother glass 100 by being spaced apart from the first display area DA1 by a certain distance in a first direction (x-axis direction). Also, a second display area DA2 may be positioned on a lower left side of the mother glass 100 by being spaced apart from the first display area DA1 by a certain distance in a second direction (y-axis direction), and a fourth display area DA4 may be positioned on a lower right side of the mother glass 100 by being spaced apart from the second display area DA2 by a certain distance in the first direction (x-axis direction). However, embodiments according to the present disclosure are not limited thereto, and the mother glass 100 may include a plurality of display areas DA in various manners.

The peripheral area PA may be an area where images are not displayed, and may entirely or partially surround the display areas DA. A driver for providing an electrical signal or power to a pixel circuit corresponding to each of the plurality of pixels may be arranged in the peripheral area PA. A pad, which is an area to which an electronic element or a printed circuit board may be electrically connected, may be arranged in the peripheral area PA.

As illustrated in FIG. 1, the peripheral area PA of the mother glass 100 may include a first peripheral area PA1 and a second peripheral area PA2, the first peripheral area PA1 being between the first display area DA1 and the second display area DA2, and the second peripheral area PA2 being between the first display area DA1 and the third display area DA3. The first peripheral area PA1 of the mother glass 100 may include a portion between the third display area DA3 and the fourth display area DA4 of the mother glass 100 as well as a portion between the first display area DA1 and the second display area DA2 of the mother glass 100. Similarly, the second peripheral area PA2 of the mother glass 100 may include a portion between the second display area DA2 and the fourth display area DA4 of the mother glass 100 as well as a portion between the first display area DA1 and the third display area DA3 of the mother glass 100.

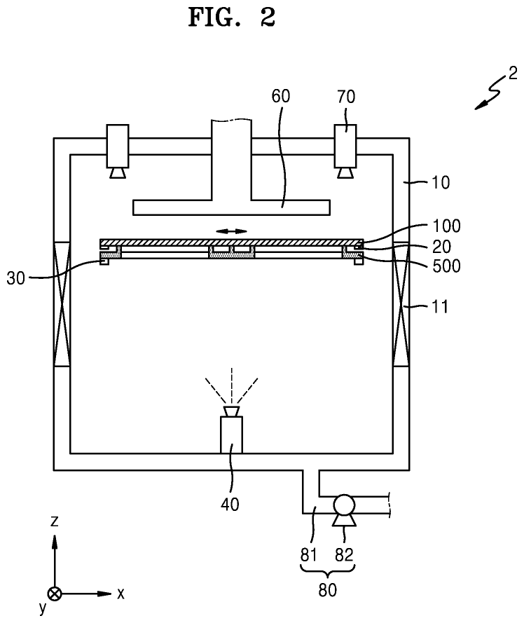

FIG. 2 is a cross-sectional view of a manufacturing apparatus for a manufacturing method, according to some embodiments. As illustrated in FIG. 2, according to some embodiments, the manufacturing method may be performed by using an apparatus 2 for manufacturing a display apparatus.

The apparatus 2 for manufacturing the display apparatus may include a chamber 10, a first support portion 20, a second support portion 30, a mask frame assembly 500, a deposition source 40, a magnetic force portion 60, a vision portion 70, and a pressure controller 80.

The chamber 10 may have a space therein, and a portion of the chamber 10 may be opened. In this regard, a gate valve 11 may be provided in the opened portion of the chamber 10. In this case, the opened portion of the chamber 10 may be opened or closed according to the operation of the gate valve 11.

The mother glass 100 may be seated on and supported by the first support portion 20. In this case, the first support portion 20 may be in the form of a plate fixed inside the chamber 10. Moreover, the first support portion 20 may be in the form of a shuttle on which the mother glass 100 is seated, the shuttle being linearly movable inside the chamber 10. The first support portion 20 may include an electrostatic chuck or an adhesive chuck that is fixed to the chamber 10 or arranged in the chamber 10 to move up and down inside the chamber 10. Hereinafter, for convenience of description, a case where the first support portion 20 is in the form of a plate fixed inside the chamber 10 will be mainly described in more detail.

The mask frame assembly 500 may be seated on the second support portion 30. In this case, the second support portion 30 may be arranged inside the chamber 10. The second support portion 30 may finely adjust a position of the mask frame assembly 500. For example, the second support portion 30 may include a separate driver or aligner to move the mask frame assembly 500 in various directions.

Moreover, the second support portion 30 may be in the form of a shuttle. In this case, the mask frame assembly 500 may be seated on the second support portion 30, and the second support portion 30 may transport the mask frame assembly 500. For example, the second support portion 30 may move out of the chamber 10 and enter the chamber 10 from the outside of the chamber 10 after the mask frame assembly 500 is seated on the second support portion 30.

The first support portion 20 and the second support portion 30 may be formed as one body and may include a movable shuttle. In this case, the first support portion 20 and the second support portion 30 may have a structure that fixes the mask frame assembly 500 and the mother glass 100 in a state in which the mother glass 100 is seated on the mask frame assembly 500, and may also linearly move the mother glass 100 and the mask frame assembly 500 simultaneously (or concurrently).

However, hereinafter, for convenience of description, a case where the first support portion 20 and the second support portion 30 are formed to be distinguishable from each other and arranged at different positions inside the chamber 10 will be mainly described in more detail.

The deposition source 40 may be arranged to face the mask frame assembly 500. In this case, a deposition material may be accommodated in (or passed through) the deposition source 40 and may be heated to be evaporated or sublimated. The deposition source 40 may be arranged to be fixed inside the chamber 10 or may be arranged inside the chamber 10 to be linearly movable in one direction. However, hereinafter, for convenience of description, a case where the deposition source 40 is arranged to be fixed inside the chamber 10 will be mainly described in more detail.

The mask frame assembly 500 may be arranged inside the chamber 10. The mask frame assembly 500 may be arranged to face the mother glass 100. The mask frame assembly 500 may include a plurality of opening portions 550. The deposition material may be deposited on the mother glass 100 through the opening portions 550. Further detailed description of the mask frame assembly 500 will be provided below.

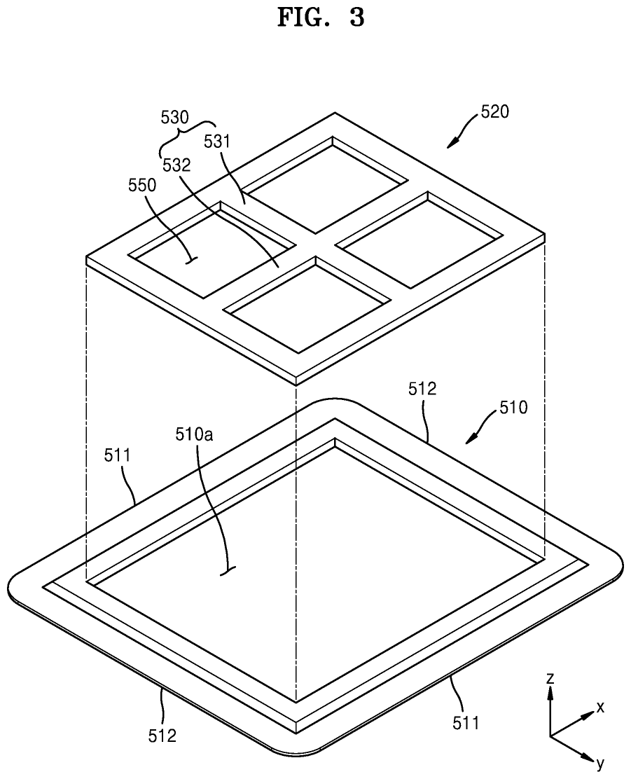

Moreover, in order for the deposition material to be deposited on the upper surface of the mother glass 100, the mother glass 100 is seated on the first support portion 20 so that the upper surface of the mother glass 100 faces the deposition source 40. That is, the upper surface of the mother glass 100 faces an upper surface of a mask 520 (see FIG. 3).

The magnetic force portion 60 may be arranged inside the chamber 10 to face a lower surface of the mother glass 100. In this case, the magnetic force portion 60 may add a force to the mask frame assembly 500 toward the mother glass 100 by applying a magnetic force to the mask frame assembly 500. In particular, the magnetic force portion 60 may prevent or reduce sagging of the mask frame assembly 500 and may bring the mask frame assembly 500 adjacent to the mother glass 100. Also, the magnetic force portion 60 may maintain a uniform distance between the mask frame assembly 500 and the mother glass 100.

The vision portion 70 may be provided in the chamber 10 and may capture images of positions of the mother glass 100 and the mask frame assembly 500. In this case, the vision portion 70 may include a camera that captures images of the mother glass 100 and the mask frame assembly 500. The positions of the mother glass 100 and the mask frame assembly 500 may be identified based on the images captured by the vision portion 70, and the first support portion 20 may finely adjust the position of the mother glass 100, or the second support portion 30 may finely adjust the position of the mask frame assembly 500. However, hereinafter, a case where the second support portion 30 finely adjusts the position of the mask frame assembly 500 to align the positions of the mother glass 100 and the mask frame assembly 500 will be mainly described in more detail.

The pressure controller 80 may be connected to the chamber 10 to control an internal pressure of the chamber 10. For example, the pressure controller 80 may adjust the internal pressure of the chamber 10 to be identical to or similar to the atmospheric pressure. Also, the pressure controller 80 may adjust the internal pressure of the chamber 10 to be identical to or similar to the vacuum state.

The pressure controller 80 may include a connection pipe 81 connected to the chamber 10 and a pump 82 provided on the connection pipe 81. In this case, according to the operation of the pump 82, external air may be introduced through the connection pipe 81, or gas inside the chamber 10 may be discharged to the outside through the connection pipe 81.

Moreover, the apparatus 2 for manufacturing the display apparatus as described above may be used in a method of manufacturing a display apparatus, according to some embodiments. For example, when the pressure controller 80 makes the inside of the chamber 10 identical or similar to the atmospheric pressure, the gate valve 11 may operate to open the opened portion of the chamber 10.

Thereafter, the mother glass 100 may be inserted into the chamber 10 from the outside of the chamber 10. In this case, the mother glass 100 may be inserted into the chamber 10 in various manners or using various mechanisms. For example, the mother glass 100 may be inserted into the chamber 10 from the outside of the chamber 10 through a robot arm arranged outside the chamber 10. When the first support portion 20 is in the form of a shuttle, after the first support portion 20 is transported from the inside of the chamber 10 to the outside of the chamber 10, the mother glass 100 may be seated on the first support portion 20 by using the separate robot arm arranged outside the chamber 10, and the first support portion 20 may be inserted into the chamber 10 from the outside of the chamber 10. Hereinafter, for convenience of description, a case where the mother glass 100 is inserted into the chamber 10 from the outside of the chamber 10 by using the robot arm arranged outside the chamber 10 will be mainly described in more detail.

The mask frame assembly 500 may be arranged inside the chamber 10 as described above. Similar to the mother glass 100, the mask frame assembly 500 may be inserted into the chamber 10 from the outside of the chamber 10. In this case, the first support portion 20 and the second support portion 30 are in the form of a shuttle, and accordingly, the mother glass 100 and the mask frame assembly 500 may be fixed and then inserted into the chamber 10 from the outside of the chamber 10. However, hereinafter, for convenience of description, a case where only the mother glass 100 is inserted into the chamber 10 from the outside of the chamber 10 in a state in which the mask frame assembly 500 is arranged inside the chamber 10 will be mainly described in more detail.

When the mother glass 100 is inserted into the chamber 10, the mother glass 100 may be seated on the first support portion 20. The vision portion 70 may capture images of the positions of the mother glass 100 and the mask frame assembly 500. For example, the vision portion 70 may capture images of a first align mark of the mother glass 100 and a second align mark of the mask frame assembly 500. Because a separate controller is provided in the apparatus 2 for manufacturing the display apparatus, the apparatus 2 for manufacturing the display apparatus may identify the positions of the mother glass 100 and the mask frame assembly 500 based on the first align mark and the second align mark. When the positions of the mother glass 100 and the mask frame assembly 500 are identified, the second support portion 30 may finely adjust the position of the mask frame assembly 500.

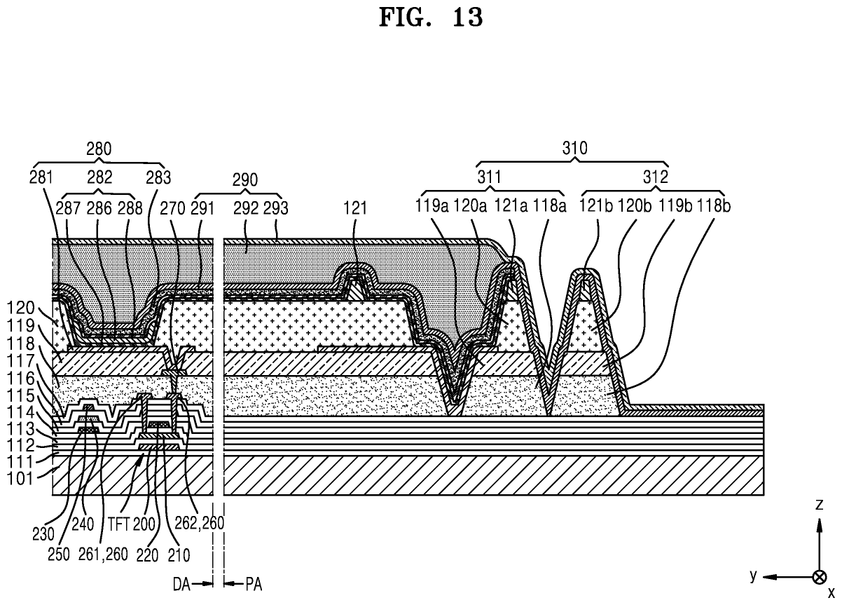

Thereafter, the deposition source 40 may operate to supply a deposition material toward the mask frame assembly 500, and the deposition material passing through the opening portions 550 of the mask frame assembly 500 may be deposited on the upper surface of the mother glass 100 as described above. In this case, the pump 82 may maintain the internal pressure of the chamber 10 to be identical or similar to the vacuum state by sucking in the gas inside the chamber 10 and discharge the gas to the outside. Accordingly, a plurality of layers stacked on the display apparatus 1 described above, for example, an intermediate layer 282 (see FIG. 13) may be formed.

FIG. 3 is a schematic exploded perspective view of the mask frame assembly 500, according to some embodiments. As illustrated in FIG. 1, according to some embodiments, the mask frame assembly 500 includes a frame 510 and a mask 520.

The frame 510 may have an opening 510a having a substantially rectangular shape, and the frame 510 itself may also have an overall rectangular shape. That is, the frame 510 may have two first sides 511 facing each other and two second sides 512 facing each other. The frame 510 may include invar, which is an iron-nickel (Fe—Ni) alloy, and a thickness of the frame 510 (in a z-axis direction) may be, for example, about 30 mm.

The mask 520 may be a mask sheet as illustrated in FIG. 3. The mask 520 may have a substantially rectangular shape in a plan view (viewed along the z-axis), and the frame 510 may be coupled to an edge of the mask 520. For example, four sides of the mask 520 may be fixed onto an upper surface of the two first sides 511 and an upper surface of the two second sides 512 of the frame 510 by using various methods such as welding or the like. The mask 520 may have an upper surface (in a +z direction) and a lower surface (in a −z direction). The mask 520 may include a plurality of opening portions 550 so that a deposition material may be deposited on a substrate through the opening portions 550. Widths or lengths of the opening portions 550 may vary according to a size or a specific configuration of an organic light-emitting display apparatus to be manufactured.

A portion of the mask 520 may sag due to a weight of the mask 520. The mask 520 may be arranged or positioned on a plurality of auxiliary sticks to significantly reduce the sagging of the mask 520 due to the weight of the mask 520. The plurality of auxiliary sticks may extend in a first direction (x-axis direction) to traverse the opening 510a of the frame 510 or may extend in a second direction (y-axis direction) crossing the first direction (x-axis direction). One end and the other end of each of the plurality of auxiliary sticks are coupled to an upper surface of the frame 510 by using various methods such as welding or the like. The auxiliary sticks may include stainless use steel (SUS), which is a type of stainless steel, and a thickness of an auxiliary stick (in the z-axis direction) may be about 100 um.

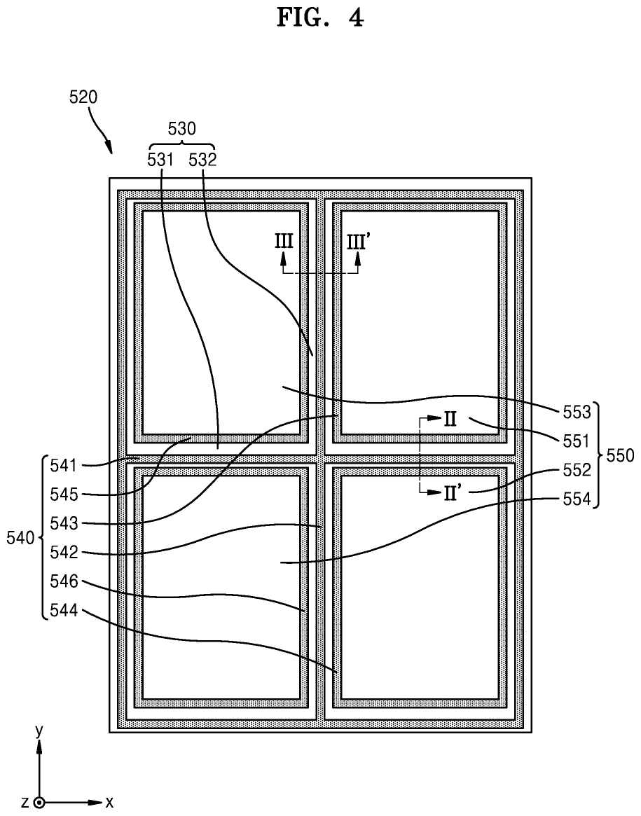

FIG. 4 is a plan view of the mask 520 of the mask frame assembly 500, according to some embodiments. As illustrated in FIG. 4, the mask 520 may be a mask provided in the aforementioned apparatus 2 for manufacturing the display apparatus. For example, the mask 520 may be an open mask, that is, a mask for depositing a deposition material on the entire surface of each of the display areas DA of the mother glass 100. Sizes of the opening portions 550 of the mask 520 may corresponding to sizes of the display areas DA of the mother glass 100. The deposition material may pass through the opening portions 550 of the mask 520 to form an unpatterned layer on the display areas DA of the mother glass 100.

The mask 520 may include a shielding portion 530 including a metallic material, and the shielding portion 530 forms a body of the mask 520. For example, the shielding portion 530 may include a first shielding portion 531 extending in the first direction (x-axis direction) and a second shielding portion 532 extending in the second direction (y-axis direction) crossing the first direction (x-axis direction).

The mask 520 may include a plurality of first shielding portions 531 extending in the first direction (x-axis direction). The plurality of first shielding portions 531 may be spaced apart from each other in the second direction (y-axis direction). For example, the first shielding portions 531 may be parallel to each other. First shielding portions 531 arranged at both ends, among the plurality of first shielding portions 531 spaced apart from each other in the second direction (y-axis direction), may correspond to an outer periphery of the mask 520, in particular, a horizontal side of the outer periphery of the mask 520.

Also, the mask 520 may include a plurality of second shielding portions 532 extending in the second direction (y-axis direction). The plurality of second shielding portions 532 may be spaced apart from each other in the first direction (x-axis direction). For example

, the second shielding portions 532 may be parallel to be each other. Second shielding portions 532 arranged at both ends, among the plurality of second shielding portions 532 spaced apart from each other in the first direction (x-axis direction), may correspond to an outer periphery of the mask 520, for example, a vertical side of the outer periphery of the mask 520.

The first shielding portions 531 and the second shielding portions 532 may cross each other. For example, the first shielding portions 531 and the second shielding portions 532 may vertically cross each other. In this case, the mask 520 may have a rectangular or square shape on a plane. Moreover, the first shielding portions 531 and the second shielding portions 532 may be formed as one body. That is, portions where the first shielding portions 531 and the second shielding portions 532 cross each other may be formed as one body and may not be superimposed or overlapped.

The plurality of first shielding portions 531 and the plurality of second shielding portions 532 may define the plurality of opening portions 550. The first shielding portions 531 may define horizontal sides of the opening portions 550, and the second shielding portions 532 may define vertical sides of the opening portions 550. As described above, the deposition material may pass through the plurality of opening portions 550 and be deposited on the upper surface of the mother glass 100.

The plurality of opening portions 550 may be spaced apart from each other at regular intervals in the first direction (x-axis direction) and/or the second direction (y-axis direction). For example, as illustrated in FIG. 4, a first opening portion 551 may be positioned at an upper right side of the mask 520, and a second opening portion 552 may be positioned on a lower right side of the mask 520 by being spaced apart from the first opening portion 551 by a distance equal to a width of the first shielding portion 531 in the second direction (y-axis direction). As illustrated in FIG. 2, the upper surface of the mask 520 faces the upper surface of the mother glass 100 in the apparatus 2 for manufacturing the display apparatus. Accordingly, in the apparatus 2 for manufacturing the display apparatus, the first opening portion 551 positioned on the upper right side of the mask 520 may correspond to the first display area DA1 positioned on the upper left side of the mother glass 100. Also, in the apparatus 2 for manufacturing the display apparatus, the second opening portion 552 positioned on the lower right side of the mask 520 may correspond to the second display area DA2 positioned on the lower left side of the mother glass 100.

In addition, as illustrated in FIG. 4, a third opening portion 553 may be positioned at an upper left side of the mask 520 by being spaced apart from the first opening portion 551 by a distance equal to a width of the second shielding portion 532 in the first direction (x-axis direction), and a fourth opening portion 554 may be positioned on a lower left side of the mask 520 by being spaced apart from the third opening portion 553 by a distance equal to the width of the first shielding portion 531 in the second direction (y-axis direction).

Similar to the first opening portion 551 and the second opening portion 552, in the apparatus 2 for manufacturing the display apparatus, the third opening portion 553 positioned on the upper left side of the mask 520 may correspond to the third display area DA3 positioned on the upper right side of the mother glass 100. Also, in the apparatus 2 for manufacturing the display apparatus, the fourth opening portion 554 positioned on a lower left side of the mask 520 may correspond to the fourth display area DA4 positioned on the lower left side of the mother glass 100.

Although the mask 520 including four opening portions 550 is illustrated in FIG. 4, one or more embodiments are not limited thereto. The number of opening portions 550 may vary according to the number of display areas DA included in the display apparatus 1 being manufactured.

Also, the mask 520 may include a protrusion 540. The protrusion 540 may cause the mask 520 and the mother glass 100 to be spaced apart from each other. The protrusion 540 may protrude from one surface, for example, an upper surface of the shielding portion 530.

The protrusion 540 may be spaced apart from a periphery of the opening portion 550 to the outside. For example, the protrusion 540 may include a first protrusion 541 located on the first shielding portion 531 and a second protrusion 542 located on the second shielding portion 532. The first protrusion 541 may extend along the first shielding portion 531, and the second protrusion 542 may extend along the second shielding portion 532. Moreover, the first protrusion 541 and the second protrusion 542 may be provided as one body. For example, the first protrusion 541 and the second protrusion 542 may cross each other and have a mesh shape.

However, embodiments according to the present disclosure are not limited thereto. The protrusion 540 may not be spaced apart from the periphery of the opening portion 550 and may be arranged to contact the periphery of the opening portion 550. Because the protrusion 540 is arranged to contact the periphery of the opening portion 550, a shadow may not be formed on the mother glass 100 during a deposition process. For example, the protrusion 540 may include a third protrusion 543 which contacts the first opening portion 551 and circumferentially surrounds the first opening portion 551. The third protrusion 543 may be consecutively arranged along a periphery of the first opening portion 551 to form a closed-loop. That is, a portion of the third protrusion 543 passes through the first shielding portion 531, and a portion of the third protrusion 543 passes through the second shielding portion 532.

Also, the protrusion 540 may include a fourth protrusion 544, a fifth protrusion 545, and a sixth protrusion 546. The fourth protrusion 544 contacts the second opening portion 552 and circumferentially surrounds the second opening portion 552. That is, the fourth protrusion 544 is consecutively arranged along a periphery of the second opening portion 552 to form a closed-loop. The fifth protrusion 545 contacts the third opening portion 553 and circumferentially surrounds the third opening portion 553. That is, the fifth protrusion 545 is consecutively arranged along a periphery of the third opening portion 553 to form a closed-loop. The sixth protrusion 546 contacts the fourth opening portion 554 and circumferentially surrounds the fourth opening portion 554. That is, the sixth protrusion 546 is consecutively arranged along a periphery of the fourth opening portion 554 to form a closed-loop. The fourth protrusion 544, the fifth protrusion 545, and the sixth protrusion 546 pass through both the first shielding portion 531 and the second shielding portion 532.

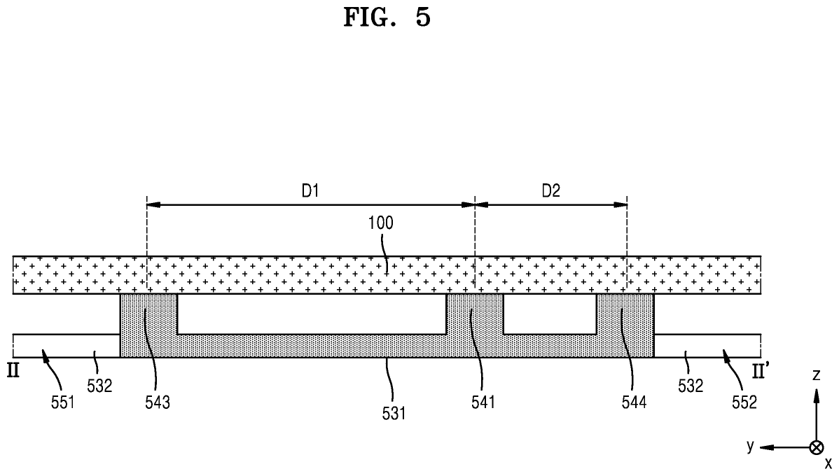

FIG. 5 is a schematic cross-sectional view of the mask 520, taken along a line II-II′ of FIG. 4. In FIG. 5, the mother glass 100 is also illustrated for convenience of description. As illustrated in FIG. 5, the first shielding portion 531 may contact the first opening portion 551 and the second opening portion 552. The first protrusion 541 may be located on the first shielding portion 531. Also, the third protrusion 543 may be located on the first shielding portion 531 to contact the first opening portion 551, and the fourth protrusion 544 may be located on the first shielding portion 531 to contact the second opening portion 552. The first protrusion 541, the third protrusion 543, and the fourth protrusion 544 may be formed as one body with the first shielding portion 531. For example, the first protrusion 541, the third protrusion 543, and the fourth protrusion 544 may be formed as one body with the first shielding portion 531 by selectively half-etching a mother material of the first shielding portion 531. Accordingly, a height of the first protrusion 541, a height of the third protrusion 543, and a height of the fourth protrusion 544 may be equal.

In a second direction (y-axis direction), a distance of the first protrusion 541 from the opening portion 550 on one side of the first shielding portion 531 may be different from a distance of the first protrusion 541 from the opening portion 550 on the other side of the first shielding portion 531. For example, a distance of the first protrusion 541 from the first opening portion 551 may be different from a distance of the first protrusion 541 from the second opening portion 552. The first opening portion 551 contacts the third protrusion 543, and the second opening portion 552 contacts the fourth protrusion 544. That is, a first distance D1 between the first protrusion 541 and the third protrusion 543 may be different from a second distance D2 between the first protrusion 541 and the fourth protrusion 544.

When a deposition material is deposited on the mother glass 100 by using the aforementioned apparatus 2 for manufacturing the display apparatus, a magnetic force is applied to the mask frame assembly 500 by the magnetic force portion 60 of the apparatus 2 for manufacturing the display apparatus. As described above, when the protrusion 540 is arranged to contact the periphery of the opening portion 550, the protrusion 540 in contact with the periphery of the opening portion 550 may excessively contact the mother glass 100 by the magnetic force. Accordingly, defects may occur due to a damage to the mask 520.

However, in the case of the mask frame assembly 500 according to some embodiments, the first distance D1 between the first protrusion 541 and the third protrusion 543 is different from the second distance D2 between the first protrusion 541 and the fourth protrusion 544. For example, the first distance D1 is longer than the second distance D2. Accordingly, a magnetic force, which is greater than a magnetic force applied to a portion between the first protrusion 541 and the fourth protrusion 544 of the first shielding portion 531, is applied to a portion between the first protrusion 541 and the third protrusion 543 of the first shielding portion 531.

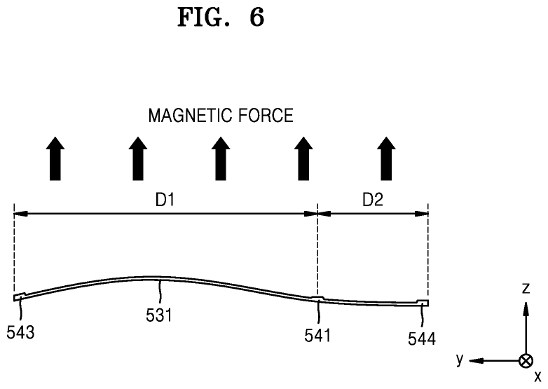

Thus, as illustrated in FIG. 6, which is a simulation result indicating a degree of bending of the first shielding portion 531 of the mask frame assembly 500 according to some embodiments in which the magnetic force is applied, a portion of the first shielding portion 531 positioned in a +y direction from the first protrusion 541, that is, a portion between the first protrusion 541 and the third protrusion 543 of the first shielding portion 531, is bent in a direction (+z direction) of the mother glass 100.

Therefore, the third protrusion 543 is spaced apart from the mother glass 100 in an opposite direction (−z direction) of the mother glass 100. Moreover, as illustrated in FIG. 6, a portion of the first shielding portion 531 positioned in a −y direction from the first protrusion 541, that is, a portion between the first protrusion 541 and the fourth protrusion 544 of the first shielding portion 531, may be rotated downward (−z direction) by the principle of the lever. In this case, a support point of the lever may be the first protrusion 541.

Accordingly, the fourth protrusion 544 is spaced apart from the mother glass 100 in the opposite direction (−z direction) of the mother glass 100. Because the third protrusion 543 and the fourth protrusion 544 are spaced apart from the mother glass 100, defects caused when the protrusion 540 in contact with the periphery of the opening portion 550 excessively contacts the mother glass 100 by the magnetic force may be significantly reduced.

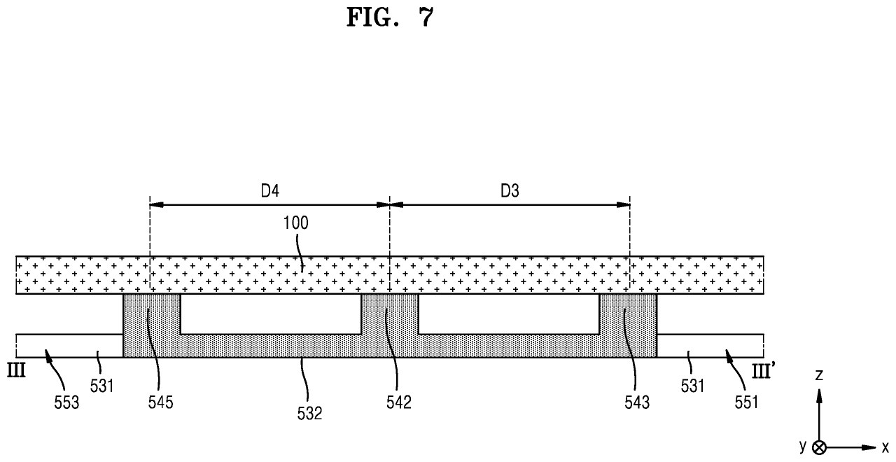

FIG. 7 is a schematic cross-sectional view of the mask 520, taken along a line III-III′ of FIG. 4. In FIG. 7, the mother glass 100 is also illustrated for convenience of description. As illustrated in FIG. 7, the second shielding portion 532 may contact the first opening portion 551 and the third opening portion 553. The second protrusion 542 may be located on the second shielding portion 532. Also, the third protrusion 543 may be located on the second shielding portion 532 to contact the first opening portion 551, and the fifth protrusion 545 may be located on the second shielding portion 532 to contact the third opening portion 553. The second protrusion 542, the third protrusion 543, and the fifth protrusion 545 may be formed as one body with the second shielding portion 532. For example, the second protrusion 542, the third protrusion 543, and the fifth protrusion 545 may be formed as one body with the second shielding portion 532 by selectively half-etching a mother material of the second shielding portion 532. Accordingly, a height of the second protrusion 542, the height of the third protrusion 543, and a height of the fifth protrusion 545 may be equal.

In a first direction (x-axis direction), a distance of the second protrusion 542 from the opening portion 550 on one side of the second shielding portion 532 may be equal to a distance of the second protrusion 542 from the opening portion 550 on the other side of the second shielding portion 532. For example, a distance of the second protrusion 542 from the first opening portion 551 may be equal to a distance of the second protrusion 542 from the third opening portion 553. The first opening portion 551 contacts the third protrusion 543, and the third opening portion 553 contacts the fifth protrusion 545. That is, a third distance D3 between the second protrusion 542 and the third protrusion 543 may be equal to a fourth distance D4 between the second protrusion 542 and the fifth protrusion 545.

As described above, the opening portion 550 and the shielding portion 530 of the mask 520 corresponds to the display area DA and the peripheral area PA of the mother glass 100, respectively. For example, the first opening portion 551 and the third opening portion 553 corresponds to the first display area DA1 and the third display area DA3, respectively, and the second shielding portion 532 corresponds to the second peripheral area PA2. As described above, a driver for providing an electrical signal or power to a pixel circuit corresponding to each of the plurality of pixels may be arranged in the peripheral area PA. Because the second peripheral area PA2 is between the first display area DA1 and the third display area DA3, for example, a driver for providing an electrical signal or power to a pixel circuit of a pixel of the first display area DA1 and a pixel circuit of a pixel of the third display area DA3 may be arranged in the second peripheral area PA2.

As will be described in more detail below, a portion of the mother glass 100, in which the driver for providing an electrical signal or power to the pixel circuit of the pixel of the first display area DA1 is arranged, corresponds to a portion between the second protrusion 542 and the third protrusion 543. Also, a portion of the mother glass 100, in which the driver for providing an electrical signal or power to the pixel circuit of the pixel of the third display area DA3 is arranged, corresponds to a portion between the second protrusion 542 and the fifth protrusion 545. Accordingly, by making the third distance D3 between the second protrusion 542 and the third protrusion 543 equal to the fourth distance D4 between the second protrusion 542 and the fifth protrusion 545, space utilization of the second peripheral area PA2 of the mother glass 100 may be significantly increased.

Although the mask frame assembly has been described, one or more embodiments are not limited thereto. A method of manufacturing a display apparatus by using the mask frame assembly and a display apparatus manufactured thereby will also fall within the scope of the disclosure. Hereinafter, the method of manufacturing the display apparatus will be described.

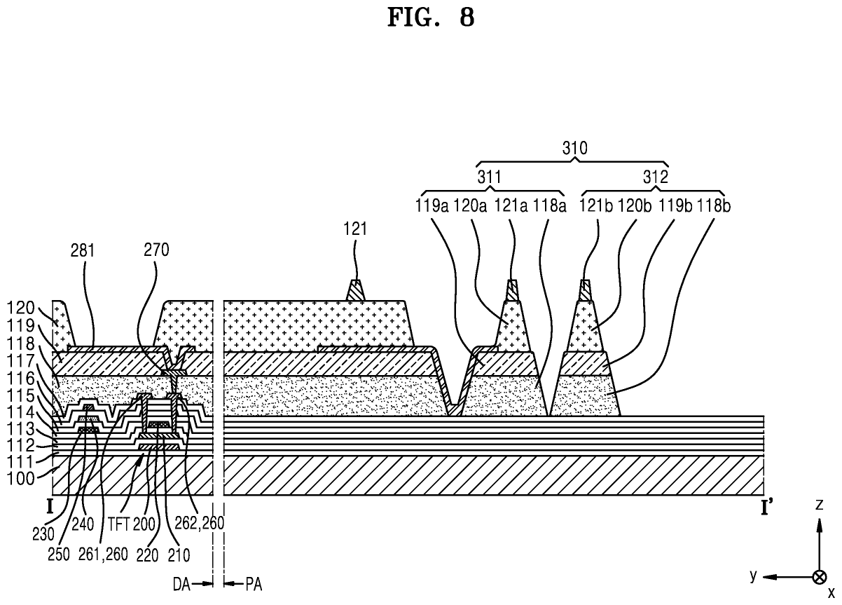

FIG. 8 is a schematic cross-sectional view of the display apparatus 1, taken along a line I-I′ of FIG. 1. As illustrated in FIG. 8, a buffer layer 111 may be formed on the mother glass 100, the buffer layer 111 including silicon oxide, silicon nitride, or silicon oxynitride. The buffer layer 111 may increase the smoothness of the upper surface of the mother glass 100 and prevent metal atoms or impurities from diffusing from the mother glass 100 into a first semiconductor layer 210 arranged above the buffer layer 111. The buffer layer 111 may be a layer or layers including silicon oxide, silicon nitride, or silicon oxynitride.

The thin-film transistor layer TFT may be formed on the buffer layer 111. As illustrated in FIG. 8, the thin-film transistor layer TFT may include the first semiconductor layer 210, a first gate layer 220, a conductive layer 230, a second semiconductor layer 240, and a second gate layer 250. Also, in order to ensure insulation between layers included in the thin-film transistor layer TFT, the thin-film transistor layer TFT may include a plurality of inorganic insulating layers 113, 114, 115, 116, and 117.

The first semiconductor layer 210 may include a silicon semiconductor. For example, the first semiconductor layer 210 may include amorphous silicon or polysilicon. For example, the first semiconductor layer 210 may include polysilicon crystalized at a low temperature. When necessary, ions may be implanted into at least a portion of the first semiconductor layer 210.

The first gate layer 220 may include a metal, an alloy, a conductive metal oxide, or a transparent conductive material. For example, the first gate layer 220 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO). The first gate layer 220 may have a multi-layered structure, for example, a two-layer structure of Mo/Al or a three-layer structure of Mo/Al/Mo.

In order to ensure insulation between the first semiconductor layer 210 and the first gate layer 220, a first gate insulating layer 113 may be between the first semiconductor layer 210 and the first gate layer 220 to cover the first semiconductor layer 210. The first gate insulating layer 113 may be an inorganic insulating layer including an inorganic material such as silicon oxide, silicon nitride, and/or silicon oxynitride. A first interlayer insulating layer 114 may be formed to cover the first gate layer 220. The first interlayer insulating layer 114 may be an inorganic insulating layer including an inorganic material such as silicon oxide, silicon nitride, and/or silicon oxynitride.

The conductive layer 230 may be formed on the first interlayer insulating layer 114. The conductive layer 230 may include a metal, an alloy, a conductive metal oxide, or a transparent conductive material. For example, the conductive layer 230 may include Ag, an alloy containing silver, Mo, an alloy containing molybdenum, Al, an alloy containing aluminum, AlN, W, WN, Cu, Ni, Cr, CrN, Ti, Ta, Pt, Sc, ITO, or IZO. The conductive layer 230 may have a multi-layered structure, for example, a two-layer structure of Mo/Al or a three-layer structure of Mo/Al/Mo. A second interlayer insulating layer 115 may be formed to cover the conductive layer 230. The second interlayer insulating layer 115 may be an inorganic insulating layer including an inorganic material such as silicon oxide, silicon nitride, and/or silicon oxynitride.

The second semiconductor layer 240 may be formed on the second interlayer insulating layer 115, and the second gate layer 250 may be arranged above the second semiconductor layer 240. The second semiconductor layer 240 may include an oxide semiconductor, and the second gate layer 250 may include a metal, an alloy, a conductive metal oxide, or a transparent conductive material. For example, the second gate layer 250 may include Ag, an alloy containing silver, Mo, an alloy containing molybdenum, Al, an alloy containing aluminum, AlN, W, WN, Cu, Ni, Cr, CrN, Ti, Ta, Pt, Sc, ITO, or IZO. The second gate layer 250 may have a multi-layered structure, for example, a two-layer structure of Mo/Al or a three-layer structure of Mo/Al/Mo.

In order to ensure insulation between the second semiconductor layer 240 and the second gate layer 250, a second gate insulating layer 116 covering the second semiconductor layer 240 may be between the second semiconductor layer 240 and the second gate layer 250. The second gate insulating layer 116 may be an inorganic insulating layer including an inorganic material such as silicon oxide, silicon nitride, and/or silicon oxynitride.

A third interlayer insulating layer 117 may be formed to cover the second gate layer 250. The third interlayer insulating layer 117 may be an inorganic insulating layer including an inorganic material such as silicon oxide, silicon nitride, and/or silicon oxynitride.

As illustrated in FIG. 8, a first connection electrode layer 260 including a source electrode 261 and a drain electrode 262 may be formed on the third interlayer insulating layer 117. A first planarization layer 118 may be formed to cover the first connection electrode layer 260. The first planarization layer 118 may include an organic insulating material. For example, the first planarization layer 118 may include photoresist, benzocyclobutene (BCB), polyimide, hexamethyldisiloxane (HMDSO), polymethyl methacrylate (PMMA), polystyrene (PS), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

A second connection electrode layer 270 may be formed on the first planarization layer 118. A second planarization layer 119 may be formed on the second connection electrode layer 270 to cover the second connection electrode layer 270. The second planarization layer 119 may include an organic insulating material. For example, the second planarization layer 119 may include photoresist, BCB, polyimide, HMDSO, PMMA, PS, a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

In the display areas DA, a display element 280 including a pixel electrode 281, an opposite electrode 283 (see FIG. 13), and an intermediate layer 282 (see FIG. 13) therebetween may be formed on the second planarization layer 119. The pixel electrode 281 may contact any one of the source electrode 261 and the drain electrode 262 through the first connection electrode layer 260 and the second connection electrode layer 270 and may be electrically connected to the thin-film transistor layer TFT as illustrated in FIG. 8. A detailed description of the display element 280 will be provided below.

A pixel-defining layer 120 may be formed on the second planarization layer 119. The pixel-defining layer 120 defines a pixel by having an opening corresponding to each sub-pixel, that is, an opening through which at least a central portion of the pixel electrode 281 is exposed. Also, the pixel-defining layer 120 may prevent arcs or the like from being generated at edges of the pixel electrode 281 by increasing a distance between the edges of the pixel electrode 281 and the opposite electrode 283 arranged above the pixel electrode 281. The pixel-defining layer 120 may be formed of an organic material such as polyimide or HMDSO.

A spacer 121 may be formed on the pixel-defining layer 120 of the peripheral area PA. The spacer 121 protrudes from the pixel-defining layer 120 to an encapsulation layer 290 (see FIG. 13) and may prevent damage to a mask or the like during a process. The spacer 121 may include an organic material such as polyimide or HMDSO.

A dam portion may be formed in the peripheral area PA. For example, a first dam portion 310 may be formed in the first peripheral area PA1. The first dam portion 310 is formed to circumferentially surround the first display area DA1, and a portion of the first dam portion 310 passes through the first peripheral area PA1. The first dam portion 310 may include a first-first dam 311 close to the first display area DA1 and a first-second dam 312 positioned outside the first-first dam 311. The first-first dam 311 may have a structure in which a first layer 118a, a second layer 119a, a third layer 120a, and a fourth layer 121a are stacked. The first layer 118a and the first planarization layer 118 may be formed simultaneously (or concurrently) by using the same material, and the second layer 119a and the second planarization layer 119 may be formed simultaneously (or concurrently) by using the same material. The third layer 120a and the pixel-defining layer 120 may be formed simultaneously (or concurrently) by using the same material, and the fourth layer 121a and the spacer 121 may be formed simultaneously (or concurrently) by using the same material.

The first-second dam 312 may prevent or significantly reduce leakage of a material for forming an organic encapsulation layer 292 (see FIG. 13) to the outside of the first dam portion 310 in a process of forming the organic encapsulation layer 292. The first-second dam 312 may have a structure in which a first layer 118b, a second layer 119b, a third layer 120b, and a fourth layer 121b are stacked. The first layer 118b and the first planarization layer 118 may be formed simultaneously (or concurrently) by using the same material, and the second layer 119b and the second planarization layer 119 may be formed simultaneously (or concurrently) by using the same material. The third layer 120b and the pixel-defining layer 120 may be formed simultaneously (or concurrently) by using the same material, and the fourth layer 121b and the spacer 121 may be formed simultaneously (or concurrently) by using the same material.

A height of the first-second dam 312 may be equal to or higher than a height of the first-first dam 311. However, one or more embodiments are not limited thereto, and the first-first dam 311 and the first-second dam 312 may include different materials and may have different heights. Although FIG. 8 illustrates that the first dam portion 310 includes the first-first dam 311 and the first-second dam 312, that is, two dams, the number of dams may be variously modified.

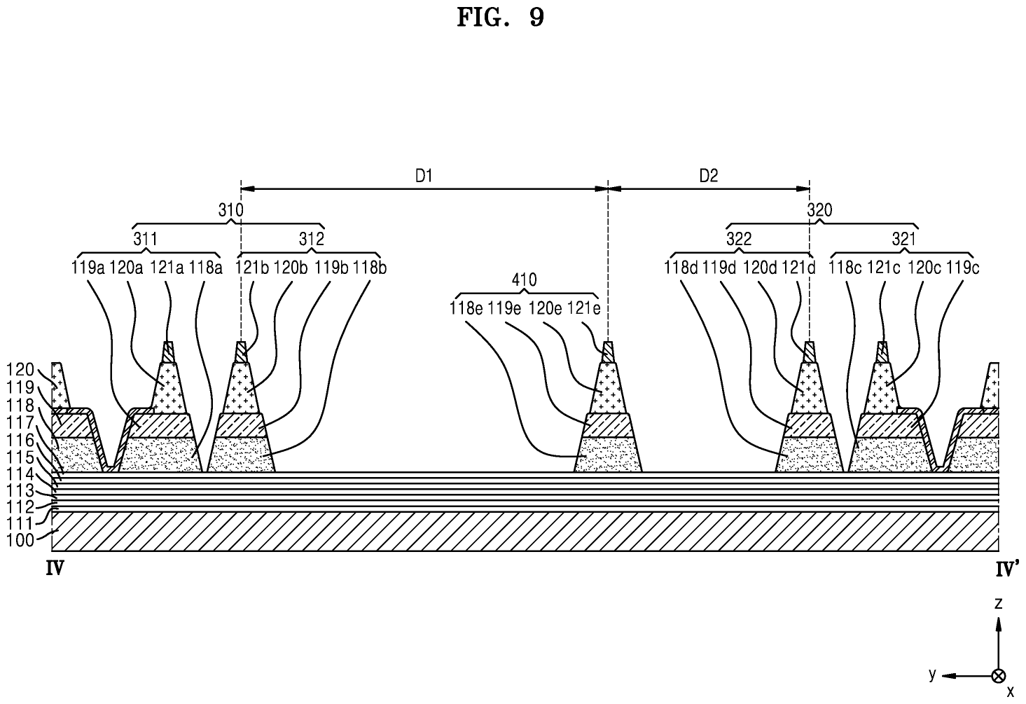

As illustrated in FIG. 9, which is a cross-sectional view of the display apparatus 1, taken along a line IV-IV′ of FIG. 1, a second dam portion 320 may be formed in the first peripheral area PA1. The second dam portion 320 is formed to circumferentially surround the second display area DA2, and a portion of the second dam portion 320 passes through the first peripheral area PA1. The second dam portion 320 includes a second-first dam 321 and a second-second dam 322. The second-first dam 321 may have a structure in which a first layer 118c, a second layer 119c, a third layer 120c, and a fourth layer 121c are stacked, and the second-second dam 322 may have a structure in which a first layer 118d, a second layer 119d, a third layer 120d, and a fourth layer 121d are stacked. Because the above description of the first dam portion 310 may also be applied to the second dam portion 320, a repeated description thereof will not be provided herein.

A first spacer 410 may be formed in the first peripheral area PA1. For example, the first spacer 410 may be between the first dam portion 310 adjacent to the first display area DA1 and the second dam portion 320 adjacent to the second display area DA2. The first spacer 410 may have a structure in which a first layer 118e, a second layer 119e, a third layer 120e, and a fourth layer 121e are stacked. The first layer 118e and the first planarization layer 118 may be formed simultaneously (or concurrently) by using the same material, and the second layer 119e and the second planarization layer 119 may be formed simultaneously (or concurrently) by using the same material. The third layer 120e and the pixel-defining layer 120 may be formed simultaneously (or concurrently) by using the same material, and the fourth layer 121e and the spacer 121 may be formed simultaneously (or concurrently) by using the same material. For example, the first dam portion 310, the second dam portion 320, and the first spacer 410 may be formed by using the same material.

Moreover, the first spacer 410 may be formed so that a distance from the first spacer 410 to the first display area DA1 is different from a distance from the first spacer 410 to the second display area DA2. The first dam portion 310 is formed adjacent to the first display area DA1, and the second dam portion 320 is formed adjacent to the second display area DA2. That is, the distance from the first spacer 410 to the first dam portion 310 may be a first distance D1, and the distance from the first spacer 410 to the second dam portion 320 may be a second distance D2 that is different from the first distance D1.

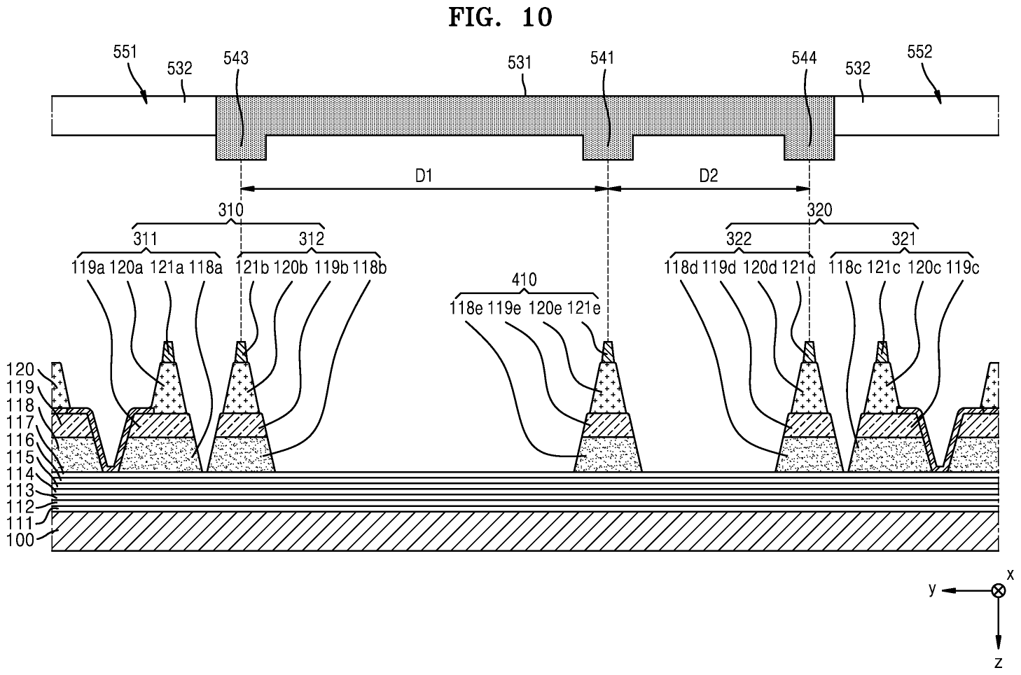

Accordingly, as illustrated in FIG. 10, which is a diagram for describing a position of the mask 520 of the mask frame assembly 500, according to some embodiments, in the apparatus 2 for manufacturing the display apparatus, the mask 520 may be arranged so that the first protrusion 541 of the mask 520 overlaps the first spacer 410. In this case, the third protrusion 543 may overlap the first-second dam 312, and the fourth protrusion 544 may overlap the second-second dam 322. Accordingly, a deposition material may be deposited on the mother glass 100 by using the mask frame assembly 500 having the first distance D1 between the first protrusion 541 and the third protrusion 543 and the second distance D2 between the first protrusion 541 and the fourth protrusion 544. As described above, because the third protrusion 543 and the fourth protrusion 544 are spaced apart from the mother glass 100, defects caused when the protrusion 540 in contact with the periphery of the opening portion 550 excessively contacts the mother glass 100 by a magnetic force may be significantly reduced.

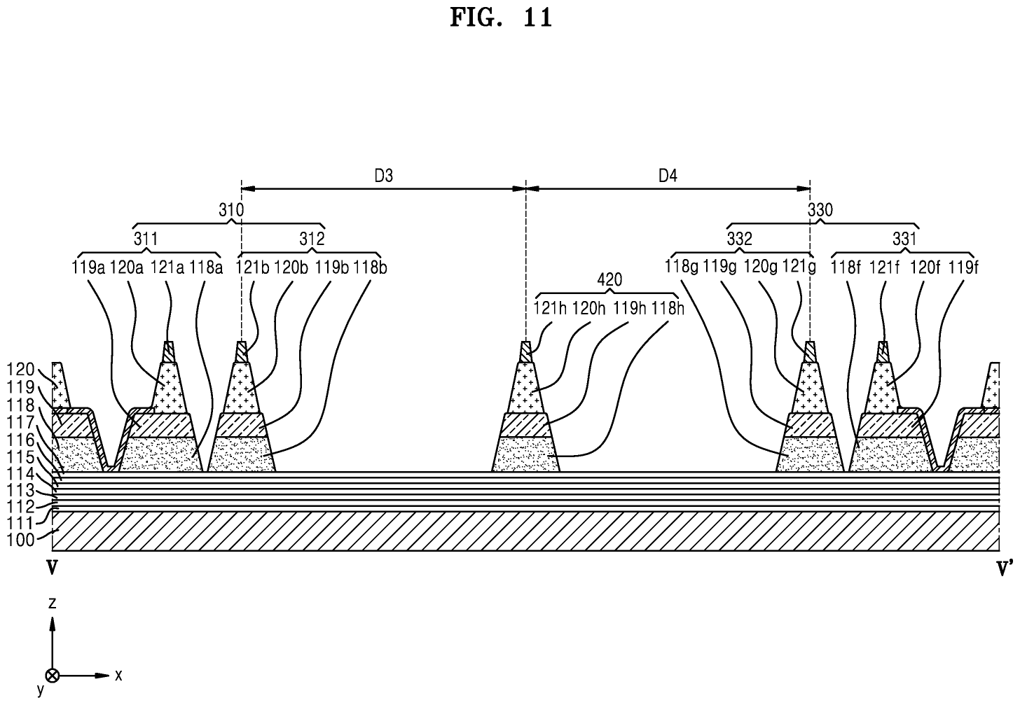

Because the first dam portion 310 is formed to circumferentially surround the first display area DA1, as illustrated in FIG. 11, which is a cross-sectional view of the display apparatus 1, taken along a line V-V′ of FIG. 1, a portion of the first dam portion 310 also passes through the second peripheral area PA2. Moreover, a third dam portion 330 may be formed in the second peripheral area PA2. The third dam portion 330 is formed to circumferentially surround the third display area DA3, and a portion of the third dam portion 330 passes through the second peripheral area PA2. The third dam portion 330 includes a third-first dam 331 and a third-second dam 332. The third-first dam 331 may have a structure in which a first layer 118f, a second layer 119f, a third layer 120f, and a fourth layer 121f are stacked, and the third-second dam 332 may have a structure in which a first layer 118g, a second layer 119g, a third layer 120g, and a fourth layer 121g are stacked. Because the above description of the first dam portion 310 may also be applied to the third dam portion 330, a repeated description thereof will not be provided herein.

A second spacer 420 may be formed in the second peripheral area PA2. For example, the second spacer 420 may be between the first dam portion 310 adjacent to the first display area DA1 and the third dam portion 330 adjacent to the third display area DA3. The second spacer 420 may have a structure in which a first layer 118h, a second layer 119h, a third layer 120h, and a fourth layer 121h are stacked. The first layer 118h and the first planarization layer 118 may be formed simultaneously (or concurrently) by using the same material, and the second layer 119h and the second planarization layer 119 may be formed simultaneously (or concurrently) by using the same material. The third layer 120h and the pixel-defining layer 120 may be formed simultaneously (or concurrently) by using the same material, and the fourth layer 121h and the spacer 121 may be formed simultaneously (or concurrently) by using the same material. For example, the first dam portion 310, the second dam portion 320, the third dam portion 330, the first spacer 410, and the second spacer 420 may be formed by using the same material. That is, the first spacer 410 and the second spacer 420 may be formed simultaneously (or concurrently).

Moreover, the second spacer 420 may be formed so that a distance from the second spacer 420 to the first display area DA1 is equal to a distance from the second spacer 420 to the third display area DA3. The first dam portion 310 is formed adjacent to the first display area DA1, and the third dam portion 330 is formed adjacent to the third display area DA3. That is, the distance from the second spacer 420 to the first dam portion 310 may be a third distance D3, and the distance from the second spacer 420 to the third dam portion 330 may be a fourth distance D4 that is equal to the third distance D3.

Accordingly, as illustrated in FIG. 11, which is a diagram for describing a position of the mask 520 of the mask frame assembly 500, according to some embodiments, in the apparatus 2 for manufacturing the display apparatus, the mask 520 may be arranged so that the second protrusion 542 of the mask 520 overlaps the second spacer 420. In this case, the third protrusion 543 may overlap the first-second dam 312, and the fifth protrusion 545 may overlap the third-second dam 332. Accordingly, a deposition material may be deposited on the mother glass 100 by using the mask frame assembly 500 having the third distance D3 between the second protrusion 542 and the third protrusion 543 and the fourth distance D4 between the second protrusion 542 and the fifth protrusion 545.

As described above, a driver for providing an electrical signal or power to the pixel circuit of the pixel of the first display area DA1 and the pixel circuit of the pixel of the third display area DA3 may be arranged in the second peripheral area PA2. For example, the driver for providing an electrical signal or power to the pixel circuit of the pixel of the first display area DA1 may be arranged in a portion between the second spacer 420 and the first dam portion 310, and the driver for driving an electrical signal or power to the pixel circuit of the pixel of the third display area DA3 may be arranged in a portion between the second spacer 420 and the third dam portion 330. Accordingly, by making the third distance D3 between the second spacer 420 and the first-second dam 312 equal to the fourth distance D4 between the second spacer 420 and the third-second dam 332, space utilization of the second peripheral area PA2 may be significantly increased.

FIG. 13 is a schematic cross-sectional view of a portion of a display apparatus manufactured by a method of manufacturing a display apparatus, according to some embodiments. A display substrate 101 may be the mother glass 100 cut along a periphery of a display portion formed on the mother glass 100.

As described above, the display element 280 includes the pixel electrode 281, the intermediate layer 282, and the opposite electrode 283. The intermediate layer 282 of the display element 280 may include a light-emitting layer 286 formed to correspond to the pixel electrode 281. The light-emitting layer 286 may include a polymer organic material or a low molecular weight organic material that emits light of a certain light. Alternatively, the light-emitting layer 286 may include an inorganic light-emitting material.

For example, the intermediate layer 282 may include a first functional layer 287 and a second functional layer 288 respectively formed below and above the light-emitting layer 286. The first functional layer 287 may include, for example, a hole transport layer (HTL), or include an HTL and a hole injection layer (HIL). The second functional layer 288 is an element arranged to cover the light-emitting layer 286 and may include an electron transport layer (ETL) and/or an electron injection layer (EIL). The first functional layer 287 and/or the second functional layer 288 may be common layers to entirely cover the mother glass 100. That is, the first functional layer 287 and/or the second functional layer 288 may be an integrated layer over a plurality of pixel electrodes 281.

The common layers, for example, the first functional layer 287 and the second functional layer 288 may be formed by using a vacuum deposition method. Hereinafter, a method of depositing the common layers will be described below in more detail. First, as illustrated in FIGS. 10 and 11, the mask 520 and the mother glass 100 are seated in the aforementioned apparatus 2 for manufacturing the display apparatus so that the upper surface of the mask 520 faces the upper surface of the mother glass 100. In this case, the mask 520 is arranged so that the first opening portion 551 and the second opening portion 552 of the mask 520 correspond to the first display area DA1 and the second display area DA2 of the mother glass 100. For example, the mask 520 is arranged so that the first protrusion 541 on the first shielding portion 531 of the mask 520 overlaps the first spacer 410. In this case, the third protrusion 543 overlaps the first-second dam 312, and the fourth protrusion 544 overlaps the second-second dam 322.

Moreover, the mask 520 is arranged so that the third opening portion 553 of the mask 520 corresponds to the third display area DA3 of the mother glass 100. For example, the mask 520 is arranged so that the second protrusion 542 on the second shielding portion 532 of the mask 520 overlaps the second spacer 420. In this case, the third protrusion 543 overlaps the first-second dam 312, and the fifth protrusion 545 overlaps the third-second dam 332.

After the mask 520 is arranged as described above, a material forming a common layer is deposited on the first to fourth display areas DA1 to DA4 of the mother glass 100 through the first to fourth opening portions 551 to 554 of the mask 520.

Moreover, the opposite electrode 283 is arranged above the display areas DA and may be formed to cover the display areas DA as illustrated in FIG. 13. That is, the opposite electrode 283 may be formed as one body with a plurality of organic light-emitting elements and may correspond to the plurality of pixel electrodes 281.

Because each organic light-emitting element may be easily damaged by external moisture, oxygen, or the like, the encapsulation layer 290 may cover and protect the organic light-emitting element. The encapsulation layer 290 may cover the display areas DA and may extend to the outside of the display areas DA. The encapsulation layer 290 may include a first inorganic encapsulation layer 291, an organic encapsulation layer 292, and a second inorganic encapsulation layer 293 as illustrated in FIG. 13.

The first inorganic encapsulation layer 291 may cover the opposite electrode 283 and may include silicon oxide, silicon nitride, and/or silicon oxynitride. When necessary, other layers such as a capping layer may be between the first inorganic encapsulation layer 291 and the opposite electrode 283. Because the first inorganic encapsulation layer 291 is formed along a structure therebelow, an upper surface of the first inorganic encapsulation layer 291 is not flat as illustrated in FIG. 13. The organic encapsulation layer 292 may cover the first inorganic encapsulation layer 291, and unlike the first inorganic encapsulation layer 291, the organic encapsulation layer 292 may have a substantially flat upper surface. For example, a portion of the organic encapsulation layer 292 corresponding to the display areas DA may have a substantially flat upper surface. The organic encapsulation layer 292 may include at least one material selected from the group consisting of polyethylene terephthalate, polyethylene naphthalate, polycarbonate, polyimide, polyethylene sulfonate, polyoxymethylene, polyarylate, and hexamethyldisiloxane. The second inorganic encapsulation layer 293 may cover the organic encapsulation layer 292 and may include silicon oxide, silicon nitride, and/or silicon oxynitride. An edge of the second inorganic encapsulation layer 293 positioned outside the display areas DA may contact the first inorganic encapsulation layer 291, and thus, the organic encapsulation layer 292 may be prevented from being exposed to the outside.

Accordingly, because the encapsulation layer 290 includes the first inorganic encapsulation layer 291, the organic encapsulation layer 292, and the second inorganic encapsulation layer 293, even when cracks occur in the encapsulation layer 290, due to this multi-layered structure, the cracks may not be connected between the first inorganic encapsulation layer 291 and the organic encapsulation layer 292 or between the organic encapsulation layer 292 and the second inorganic encapsulation layer 293. Therefore, the formation of a path through which external moisture or oxygen penetrates into the display areas DA may be prevented or significantly reduced.

According to the embodiments of the disclosure as described above, a mask frame assembly with a relatively reduced probability of defects in a manufacturing process and a method of manufacturing a display apparatus by using the mask frame assembly may be implemented. However, the scope of embodiments according to the present disclosure are not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A mask frame assembly comprising:
a mask including a plurality of opening portions; and
a frame coupled to an edge of the mask,
wherein the mask comprises:
first shielding portions extending in a first direction and parallel to each other;
second shielding portions parallel to each other and extending in a second direction crossing the first direction, such that the plurality of opening portions are defined together with the first shielding portions; and
a first protrusion on the first shielding portion, wherein, in the second direction, a distance from an opening portion on one side of the first shielding portion is different from a distance from an opening portion on another side of the first shielding portion.

2. The mask frame assembly of claim 1, wherein the first protrusion extends in the first direction.

3. The mask frame assembly of claim 1, wherein the plurality of opening portions include a first opening portion and a second opening portion, the second opening portion being spaced apart from the first opening portion in the second direction, and
the mask frame assembly further comprises a third protrusion contacting the first opening portion and circumferentially surrounding the first opening portion, wherein a portion of the third protrusion is on the first shielding portion.

4. The mask frame assembly of claim 3, further comprising a fourth protrusion contacting the second opening portion and circumferentially surrounding the second opening portion, wherein a portion of the fourth protrusion is on the first shielding portion.

5. The mask frame assembly of claim 4, wherein a height of the first protrusion, a height of the third protrusion, and a height of the fourth protrusion are equal.

6. The mask frame assembly of claim 1, wherein the mask further comprises a second protrusion on the second shielding portion, wherein, in the first direction, a distance from an opening portion on one side of the second shielding portion is equal to a distance from an opening portion on another side of the second shielding portion.

7. The mask frame assembly of claim 6, wherein the second protrusion extends in the second direction.

8. The mask frame assembly of claim 6, wherein the plurality of opening portions include a first opening portion and a third opening portion, the third opening portion being spaced apart from the first opening portion in the first direction, and
the mask frame assembly further comprises a third protrusion contacting the first opening portion and circumferentially surrounding the first opening portion, wherein a portion of the third protrusion is on the second shielding portion.

9. The mask frame assembly of claim 8, further comprising a fifth protrusion contacting the third opening portion and circumferentially surrounding the third opening portion, wherein the fifth protrusion is on the second shielding portion.

10. The mask frame assembly of claim 9, wherein a height of the first protrusion, a height of the third protrusion, and a height of the fifth protrusion are equal.

11. The mask frame assembly of claim 6, wherein the first protrusion and the second protrusion are provided as one body.

12. A method of manufacturing a display apparatus, the method comprising:
forming a first spacer in a first peripheral area between a first display area and a second display area so that a distance from the first spacer to the first display area is different from a distance from the first spacer to the second display area, the first display area and the second display area of a mother glass being adjacent to each other in a first direction;
arranging a first opening portion and a second opening portion of a mask to respectively correspond to the first display area and the second display area of the mother glass, wherein the mask is arranged such that a first protrusion on a first shielding portion of the mask overlaps the first spacer; and
depositing a deposition material on the mother glass through the first opening portion and the second opening portion of the mask.

13. The method of claim 12, wherein the forming of the first spacer comprises:
forming a first dam portion circumferentially surrounding the first display area, wherein a portion of the first dam portion passes through the first peripheral area;
forming a second dam portion circumferentially surrounding the second display area, wherein a portion of the second dam portion passes through the first peripheral area; and
forming the first spacer to be between the first dam portion and the second display area so that a distance of the first spacer from the first dam portion is different from a distance of the first spacer from the second dam portion.

14. The method of claim 13, wherein the forming of the first spacer comprises concurrently forming the first dam portion, the second dam portion, and the first spacer by using a same material.

15. The method of claim 13, wherein the arranging of the mask comprises:
arranging a third protrusion to overlap the first dam portion, the third protrusion contacting the first opening portion and circumferentially surrounding the first opening portion, wherein a portion of the third protrusion is on the first shielding portion; and
arranging a fourth protrusion to overlap the second dam portion, the fourth protrusion contacting the second opening portion and circumferentially surrounding the second opening portion, wherein a portion of the fourth protrusion is on the first shielding portion.

16. The method of claim 13, further comprising forming a second spacer in a second peripheral area between a third display area and the first display area of the mother glass so that a distance from the second spacer to the first display area is equal to a distance from the second spacer to the third display area, the third display area being spaced apart from the first display area in a second direction crossing the first direction.

17. The method of claim 16, wherein the forming of the second spacer comprises:
forming a third dam portion circumferentially surrounding the third display area, wherein a portion of the third dam portion passes through the second peripheral area; and
forming the second spacer between the first dam portion and the third dam portion such that a distance of the second spacer from the first dam portion is equal to a distance the second spacer from the third dam portion.

18. The method of claim 17, wherein the forming of the first spacer and the forming of the second spacer are performed concurrently.

19. The method of claim 18, wherein the forming of the first spacer and the forming of the second spacer comprise concurrently forming the first dam portion, the second dam portion, the third dam portion, the first spacer, and the second spacer by using a same material.

20. The method of claim 17, wherein the arranging of the mask comprises:
arranging a second protrusion to overlap the second spacer, the second protrusion being on a second shielding portion of the mask;
arranging a third protrusion to overlap the first dam portion, the third protrusion contacting the first opening portion, circumferentially surrounding the first opening portion, and being on the second shielding portion; and
arranging a fifth protrusion to overlap the third dam portion, the fifth protrusion contacting a third opening portion of the mask corresponding to the third display area of the mother glass, circumferentially surrounding the third opening portion, and being on the second shielding portion.
